(19) United States
(12) Patent Application Publication
(10) Pub. No.: US 2026/0003008 A1
(43) Pub. Date: Jan. 1, 2026

(54) Method and system for operating an energy storage device with a plurality of battery cells

(71) Applicant: Webasto SE, Stockdorf (DE)

(72) Inventor: David Bennetts, Stockdorf (DE)

(21) Appl. No.: 18/869,112

(22) PCT Filed: May 25, 2023
(86) PCT No.: PCT/EP2023/064127

§ 371 Date: Nov. 25, 2024

(30) Foreign Application Priority Data
May 25, 2022 (DE) 10 2022 113 179.3

(51) Int. Cl. G01R 31/396; H01M 10/42; H01M 10/48

(52) U.S. Cl. CPC G01R 31/396; H01M 10/425; H01M 10/482; H01M 2220/20

(57) ABSTRACT

A method and system for operating an energy store comprising a plurality of battery cells, in particular in a vehicle, where a plurality of measurements of a terminal voltage of at least one battery cell are acquired; the acquired measurements are used to carry out a filtering and a filtered measurement result is generated; the filtering of the measurements comprising a comparison operation; and the filtered measurement result is used to generate and output output data.

### CROSS-REFERENCE TO RELATED APPLICATIONS

This application is a 35 U.S.C. § 371 National Stage Entry of International Application No. PCT/EP2023/064127 filed May 25, 2023, which claims the priority benefit of German Patent Application Serial Number DE 10 2022 113 179.3 filed May 25, 2022, all of which are incorporated herein by reference in their entirety for all purposes.

### TECHNICAL FIELD

The invention relates to a method for operating an energy store comprising a plurality of battery cells, in particular in a vehicle. The invention also relates to a system for operating an energy store comprising a plurality of battery cells, in particular in a vehicle.

### BACKGROUND

The traction battery of a vehicle typically consists of a plurality of individual battery cells that are connected to one another in series, for example, in order to achieve the requisite high voltages. In particular, there is provision for battery modules that comprise a specific number of battery cells; a specific number of battery modules are then connected to produce the overall traction battery. To monitor the battery, there is usually provision for a distributed topology of a battery management system (BMS). There is provision for a central control unit connected to a multiplicity of integrated cell monitoring units via a data connection, in particular via a data bus. In this way, cell voltage and temperature, for example, are measured for the individual battery cells and monitored. The cell monitoring units are in particular integrated with a battery module in an integrated design.

The integrated cell monitoring units are usually suitable for performing basic data processing, and so not every single measurement needs to be transmitted to the central control unit. This reduces the required bandwidth and the requisite computing power of the central control unit. The effective sampling rate can also be improved in this manner.

The state of charge (SoC) of a battery is a measure of the energy stored therein. In the case of the traction battery of a vehicle, this is therefore also an indicator of the remaining range of the vehicle. The energy available in a car battery is the sum of the energy in the individual cells.

A “state of health” (SoH) of a battery may also be defined as a measure of its overall state. Typically, the SoH decreases as the age of the battery increases, among other things depending on the type of loading, the discharging and charging behavior and environmental influences.

As the traction battery makes up a substantial part of the overall price of a vehicle, the state of charge is a parameter that not only governs the reliability of a range indication but also permits optimum utilization of a valuable resource. It is therefore very important to a user that the state of charge is determined as reliably and accurately as possible.

The state of charge cannot be measured directly, however, but rather needs to be estimated on the basis of available parameters of the battery and ambient conditions. An essential parameter that indicates the state of charge consistently and reliably is the terminal voltage of a battery cell (unloaded, settled cell terminal voltage) while said battery cell is not operated under load. This value can be only estimated during vehicle operation, however, because the measurable terminal voltage continually changes on the basis of the dynamic load during the application. In particular, the terminal voltage falls during each short-term peak demand; it can also rise while the battery is charged.

Known solutions for estimating the state of charge involve, for example, functionalities for which an analog-to-digital conversion takes place being used. There may also be provision for an opportunity to average over a multiplicity of values, for instance by means of an IIR (Infinite Impulse Response) or FIR (Finite Impulse Response) filter. The filtered measurements are influenced by the individual measurements, including the measurements for cells that are being operated under load. As described above, this leads to decreased accuracy for estimating the state of charge.

The terminal voltage of the battery cells operated under load leads to a shift in the average measurement that is output by the central control unit. This leads to an inaccurate indication of the state of charge and therefore also of the remaining range of the vehicle.

DE 10 2015 114 652 A1 discloses a method for estimating the energy capacity of a battery system in a vehicle. This involves determining a voltage offset and an estimated total stack energy of the battery system. These values are used to estimate the energy capacity of the battery system.

WO 2019/025171 A1 describes a method for estimating the cell voltage, the state of charge and the battery state of a battery in combination with a load. This involves measuring a first current and a first voltage, and a cell idle voltage of the battery is estimated. An energization level of the battery is estimated on the basis of the voltage, current and a cost optimization process.

EP 2 306 214 A3 proposes a method for determining the DC impedance of a battery.

### SUMMARY

The object of the invention is to provide a method and a system for operating an energy store comprising a plurality of battery cells, in particular in a vehicle, that permits the state of charge of the battery to be determined in as accurate and fast and resource-saving a manner as possible.

This object is achieved by way of a method and a system according to the independent claims. Advantageous configurations and developments of the invention are specified in the dependent claims.

The method for operating an energy store comprising a plurality of battery cells, in particular in a vehicle, involves a plurality of measurements of a terminal voltage of at least one battery cell being acquired. The acquired measurements are used to perform a filtering, and a filtered measurement result is generated. The filtering of the measurements comprises a comparison operation. The filtered measurement result is used to generate and output output data.

In particular, the output data can comprise at least one of the acquired measurements.

This advantageously allows particularly suitable measurements to be output, for example in order to permit consistently accurate estimation of the state of charge even under changing operating conditions.

A central control unit can then compute the state of charge with improved accuracy and thereby reliably determine the remaining range of the vehicle. This leads to decreased costs as a result of better utilization of the traction battery of the vehicle and to a better impression for the user as a result of greater confidence in the indicated remaining range or operating time.

In particular, there may be provision for the method to be carried out at the level of an integrated cell monitoring unit that acquires the measurements for the battery cells of a subset of the battery cells of the energy store and monitors these battery cells. As a result, the electronics of this integrated cell monitoring unit may be in a form such that they are suitable only for the total voltage of the battery cells thus monitored, rather than for the total voltage of all of the battery cells of the energy store.

The output data can then be transmitted to a superordinate central control unit and evaluated further there, or the central control unit can use the received output data to generate a control signal for controlling the battery cells or subsets thereof.

A fundamental concept of the invention involves dealing with the measurements by way of the filtering comprising a comparison operation such that unsuitable measurements can be identified and filtered out very easily. They then do not contribute to the volume of data that is output and transmitted, and so an available bandwidth, for instance of a data connection between integrated cell monitoring units and a central control unit, is conserved. The further processing and/or evaluation of the data can also take place with lower computing power and more efficiently. The filtering involves comparing the measurements with one another and/or comparing the measurements with another value, for instance a threshold value or the limits of a range of values.

To reproduce the physical behavior of a battery cell in a theoretical model, it is typically assumed that said battery cell has at least one internal impedance, which in particular comprises a nonreactive component. The terminal voltage changes on the basis of the voltage drop across the internal impedance of the cell.

The internal impedance must therefore be included in the computation of the state of charge, but this parameter is not directly measurable either. When estimating the value, the difficulty arises that said value is influenced by various factors such as the temperature and age of the cell and by the state of charge itself. A way of estimating the state of charge should thus be chosen in which the influence of the internal impedance value is reduced as far as possible.

The relevant terminal voltage of the battery cell then most likely corresponds to the state of charge when the cell is operated with minimal load; the state of charge can therefore be determined with the best accuracy in this case. The nonreactive component of the internal impedance reacts to the changing load particularly quickly.

That is to say that assessment of the state of charge of the battery cell requires the acquired voltage values to be acquired without any load as far as possible.

The measurements of the terminal voltage are acquired in a manner known per se. The measurements can be acquired for every single battery cell; in other embodiments, acquiring can take place simultaneously for a defined set of the battery cells, for instance a set of battery cells connected in series.

Measurements of the temperature of at least one battery cell can also be acquired, for example at the same time as the terminal voltage is acquired.

In one embodiment of the method, the plurality of measurements are acquired as a time series.

By way of example, the measurements are acquired at successive times, for instance at a predefined frequency of acquiring. In particular, the measurements can be performed at fixed intervals of time from one another.

The measurements are acquired in particular over a predefined period, which may furthermore be configurable. By way of example, the measurements can be stored in a memory. The most recent measurement can also repeatedly replace the oldest measurement of the plurality of the measurements, for instance in a ring memory, so as to always evaluate a predefined number of the most recently acquired measurements or the measurements most recently acquired within the predefined period.

The filtering and production of the output data can be carried out at predefined times, for instance at regular intervals at a predefined, possibly configurable frequency or on receiving a request signal.

In another embodiment, the comparison operation comprises determining a maximum or minimum measurement of the plurality of measurements. That is to say that the comparison operation involves the measurements being compared with one another, in particular the measurements acquired within a specific period.

In particular, the output data comprises the maximum and/or minimum of the acquired measurements.

In another embodiment, a predefined, possibly configurable number of maximum or minimum measurements can be determined. Such a set of maximum or minimum measurements can also be used to determine a mean value.

In another embodiment, a median value of the plurality of the measurements or of a specific subset thereof is determined. That is to say that a comparison of the measurements with one another is used to determine the median value, which in each case is greater or less than half of each of the measurements. The value thus obtained is less susceptible to influences of short-term variances than the arithmetic mean.

The filtering can also comprise a smoothing operation over the total quantity of acquired measurements, for instance calculating a moving average.

In one development, the comparison operation comprises comparing the measurements with at least one limit value. There may be provision for a lower and/or an upper limit value in this case. Comparison with both a lower and an upper limit value results in it being determined whether the measurement lies in a specific range.

A fixed limit value may be predefined in this case, for instance by a configuration of the system.

A dynamic limit value may also be predefined, for instance in order to determine the measurements below or above the average of the total plurality of the measurements during the filtering. There may also be provision for other dynamically determined limit values, which can be determined on the basis of the plurality of measurements, for example, or which are predefined by means of a configuration.

In one embodiment, an operating state is detected and the measurements are acquired on the basis of the operating state, wherein the detected operating state is taken as a basis for triggering a control signal for resetting the acquired measurements, the control signal being generated in such a way that the acquiring of the measurements is resumed only after the end of an event and/or that measurements acquired during the event are rejected.

In one embodiment, the comparison operation comprises determining a number of measurements within a range. The output data in this case can optionally be generated such that they comprise information about a distribution of the plurality of measurements. The number may be an absolute number of acquired measurements, but it can also be indicated as a proportion of the total number of the plurality of measurements.

Alternatively or additionally, it is possible to determine within what period the measurements within the range have been acquired.

The limit or limits of the range limited at one end or at both ends may be predefined by a configuration in this case.

In another embodiment, the comparison operation results in at least one limit of the range being determined.

In such a case, the limit or limits of the range limited at one end or at both ends can be determined dynamically on the basis of the acquired plurality of the measurements, for instance in order to determine the number of measurements above the average of the acquired measurements or to determine the number of measurements in a range above or below the average.

In one example, the maximum of the measurements is first determined and then the number of measurements within a specific range below this maximum is determined. This makes it possible to check whether the maximum is a brief peak or whether it is in the region of a plateau of values of the terminal voltage.

The determination of the number of measurements within a range can be utilized for example in order to perform a plausibility check.

An evaluation of the number of measurements within a range also allows information about the state of the battery cell to be obtained, for instance in order to identify ongoing deviations from recommended parameters, which can indicate a malfunction in or damage to the battery cell, for example.

In various embodiments, the output data can comprise a combination of different information.

In one example, the output data comprise a maximum value from the plurality of acquired measurements and also a number of measurements within a range limited at one end or at both ends. The combination of this information firstly allows the measurement taken as the off-load voltage to be determined, while secondly a plausibility check can be performed.

In one development, a configuration signal is also received, wherein the measurements are evaluated on the basis of the configuration signal. The configuration signal comprises in particular configuration data, for instance for an integrated cell monitoring unit.

The evaluation of the measurements relates in particular to the filtering and/or the comparison operation comprised thereby, but other evaluation steps can also be carried out and configured on the basis of the configuration signal.

The extent of the plurality of the measurements may be configurable. In particular, the configuration signal configures a length of a time interval during which the measurements are acquired. The number of measurements can also be configured in each case as a plurality of the acquired measurements. A frequency of the acquiring of measurements can also be configured. By way of example, such a configuration signal can be used to control how many measurements are acquired and/or at what frequency and/or over what period the acquiring takes place. The configuration signal can also be used to control a specific algorithm or a functionality for the filtering, with the result that in particular the output data comprise the respective desired information. The configuration signal can also be used to control whether and how a smoothing operation is performed, in order to achieve smoothing of the output data and/or the acquired measurements.

The configuration signal can also be used to select specific battery cells for acquiring the measurements.

The configuration signal can also be used to configure a acquiring such that the terminal voltage of a subgroup of battery cells is acquired for the measurements.

The configuration signal may also comprise one or more threshold values, which are used for the comparison operation. By way of example, the configuration signal can be used to deliver a threshold value with which the measurements are compared; by way of example, the number of measurements below or above the threshold value can then be determined and output with the output data.

The configuration signal can also be used to transmit multiple threshold values that define ranges and that can be used to perform binning of the measurements, for example. That is to say that the measurements are compared with the threshold values and assigned to the respective ranges between the threshold values. Outputting the number of measurements in the ranges allows a distribution of the measurements to be indicated. In general terms, what is known as “binning” can result, for example, in the target quantities of attributes being divided into ranges in ascending order according to size; all attribute values are then replaced with the representative of the range that the value is in.

In one embodiment, an operating state is also detected and the measurements are acquired on the basis of the operating state. The detected operating state can optionally be taken as a basis for triggering a control signal for resetting the acquired measurements. In particular, the operating state is detected and/or evaluated for the energy store and/or at least one battery cell. For example, the operating state can be detected and/or evaluated for the battery cells coupled to an integrated cell monitoring unit individually and/or in their entirety.

The operating state can relate to the energy store and the battery cells comprised thereof. In particular, the operating state relates to a connected load or a charging apparatus. That is to say that the operating state can depend on whether and to what extent the energy store is loaded by a load, whether it is charged or whether it is off load, when no power is demanded.

The operating state can be detected for example by acquiring a voltage, a current and/or a demanded power.

The operating state detected can also be a charging process, that is to say that a check is performed to ascertain whether a battery cell is being charged, for example during a recuperation process. This can involve in particular acquiring a direction of current and thus determining whether charging is taking place.

The detected operating state can also be taken as a basis for triggering and processing a control signal for resetting the acquired measurements. By way of example, an event that leads to distortion of the acquired measurements can be detected. For example, a recuperation process that leads to a charging of a battery cell or of the energy store and therefore to a rise in the terminal voltage can be detected. The control signal can be generated in such a way that the acquiring of the measurements is resumed only after the end of the event and/or that measurements acquired during the event are rejected.

In another embodiment, the output value is used to determine and output a state of charge of at least one battery cell and/or of the energy store. By way of example, an integrated cell monitoring unit can generate the output data and transmit them to an external unit, for instance a central control unit, said unit determining the state of charge.

The method can advantageously be utilized to use the filtered measurements to obtain a particularly accurate and reliable range estimate.

In another embodiment, the output data can be used to determine a “state of health” (SoH) of the energy store or of a subset of the battery cells. By way of example, this can be accomplished by determining a present distribution of the measurements, in particular for a specific operating state. The present distribution can then be compared with an earlier distribution that was acquired for a comparable operating state at an earlier time. A change in the distribution can then be used to determine a change in the state of health of the measured battery cells. In particular, the SoH is indicated as a quality factor in percent. By way of example, this can indicate a degree of worsening of the state of health of the energy store with increasing age.

The system for operating an energy store comprising a plurality of battery cells, in particular in a vehicle, comprises an acquiring module configured to acquire a plurality of measurements of a terminal voltage of at least one battery cell, an evaluation module configured to use the acquired measurements to perform a filtering and to generate a filtered measurement result, the filtering of the measurements comprising a comparison operation, and an output module configured to use the filtered measurement result to generate and output output data.

The system is designed in particular to carry out the method. It therefore has the same advantages as the method according to the invention.

In particular the acquiring module, the evaluation module and the output module are integrated in a cell monitoring unit that is associated with the at least one battery cell and that is coupled to a central control unit via a data connection, in particular a data bus.

The acquiring module may be designed, in a manner known per se, to acquire the terminal voltage. The acquiring module can also be used to acquire a temperature of the at least one battery cell and/or another parameter. The acquiring module may in particular be integrated in the battery cell, or in a cell module. For example, there may be provision for an integrated cell monitoring unit, having a acquiring module, for each cell module of the energy store.

In particular, the system also has a memory module, which an integrated cell monitoring unit may likewise comprise. The acquired measurements are then stored in the memory module and are available for an evaluation, for instance by means of the filtering. The memory module may be formed such that recently acquired measurements overwrite the oldest measurements in each case, for instance in the style of a ring memory.

The integrated cell monitoring units can also comprise a reset function for the aforementioned values in order to eliminate unsuitable measurements during a rise in the voltage during the regenerative braking of the vehicle. Resetting the memory results in all values of the plurality of measurements in the memory module being overwritten, and the evaluation is performed only after the plurality of measurements have been acquired again.

The output data can be transmitted from the output module to a central control unit.

A configuration signal can be transmitted from the central control unit to the integrated cell monitoring unit in the manner described above in order to control the acquiring of the measurements and/or the evaluation by means of filtering.

A data transmission between the integrated cell monitoring units of the cell modules of the energy store and the central control unit can be carried out via a data connection, for example via a data bus, in particular in a ring configuration. The data transmission in this case is protected against failure of part of the data bus because the data transmission can be carried out in two directions. Alternatively, there may be provision for a track configuration for the data transmission.

The cell modules of the energy store are in particular-apart from the connection in series or parallel with one another-in electrically isolated form.

The central control unit may be configured to detect a charging of the energy store or of the at least one battery cell and then to generate a reset signal and to transmit said reset signal to the integrated cell monitoring unit, which is designed to then start acquiring a plurality of the measurements again.

The invention also relates to a vehicle comprising an energy store, which comprises a plurality of battery cells, an electrical load, for example an electric motor, a heating device and/or a lighting device, and also a control unit. The control unit is configured to operate the energy store in accordance with the method of the invention.

### BRIEF DESCRIPTION OF THE FIGURES

The invention is explained in more detail hereinbelow on the basis of the accompanying drawings, in which:

FIG. 1 shows an exemplary embodiment of the system;

FIG. 2 shows an exemplary embodiment of the vehicle;

FIG. 3 shows a graph with a typical voltage response for a battery cell; and

FIG. 4 shows an exemplary embodiment of the method.

### DETAILED DESCRIPTION

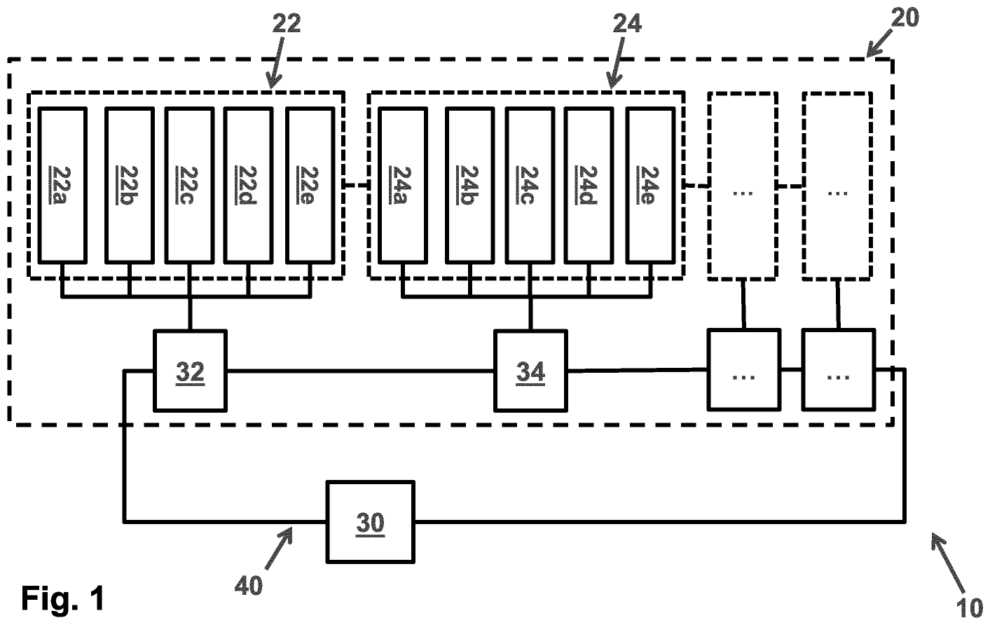

An exemplary embodiment of the system is explained with reference to FIG. 1.

The system 10 comprises an energy store 20.

The energy store 20 has multiple cell modules 22, 24, which in turn each have multiple battery cells 22a, 22b, 22c, 22d, 22e, 24a, 24b, 24c, 24d, 24e. Further cell modules are also indicated in FIG. 1.

The cell modules 22, 24 are electrically conductively coupled to one another and for instance connected to one another in series. Cell modules 22, 24 may also be connected in parallel with one another, wherein in particular a combination of series-and parallel-connected cell modules 22, 24 of the energy store 20 results in a specific total voltage and a specific capacitance of the energy store 20 being obtained.

The battery cells 22a, 22b, 22c, 22d, 22e, 24a, 24b, 24c, 24d, 24e of a cell module 22, 24 are in particular connected in series, there possibly being provision for other circuits and configurations here too.

In the example, each cell module 22, 24 comprises an integrated cell monitoring unit 32, 34, which, here, is coupled to the individual battery cells 22a, 22b, 22c, 22d, 22e, 24a, 24b, 24c, 24d, 24e.

A data bus 40 connects the integrated cell monitoring units 32, 34 to a central control unit 30 for data transfer purposes. In the exemplary embodiment, the data bus 40 is in the form of a ring bus. In other exemplary embodiments, a data connection may be provided in another way, for example via a wireless connection.

The integrated cell monitoring unit 32, 34 comprises an acquiring module, an evaluation module and an output module.

The acquiring module is configured in a manner known per se to acquire measurements for the terminal voltage of each of the connected battery cells 22a, 22b, 22c, 22d, 22e, 24a, 24b, 24c, 24d, 24e. Moreover—likewise in a manner known per se-further measurements are acquired for the temperature of the battery cells 22a, 22b, 22c, 22d, 22e, 24a, 24b, 24c, 24d, 24e.

The measurements of the terminal voltage for the individual battery cells 22a, 22b, 22c, 22d, 22e, 24a, 24b, 24c, 24d, 24e are acquired as a time series, a specific length of a time interval for acquiring the measurements being predefined. In the exemplary embodiment, this time interval can be adapted by a configuration signal from the central control unit 30.

In other exemplary embodiments, there may be provision for the cell monitoring units 32, 34 to use the acquired measurements for the terminal voltage of each of the connected battery cells 22a, 22b, 22c, 22d, 22e, 24a, 24b, 24c, 24d, 24e to check whether these values form a new maximum value of the past measurements. If this is the case, this new maximum value is stored and is output to the control unit 30 in the event of a query.

In particular, the output data can essentially comprise only one measurement. The required memory of the cell monitoring units 32, 34 can also be reduced such that only the currently maximum value in each case is stored.

In particular, the example involves the measurements being acquired at uniform intervals of time, that is to say at a substantially constant acquiring frequency, and stored by means of a memory module of the integrated cell monitoring unit 32, 34.

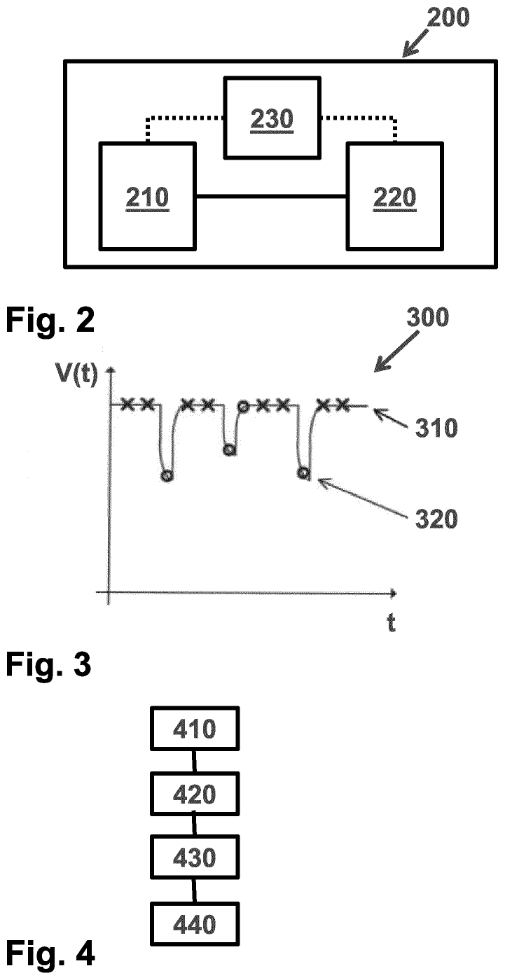

An exemplary embodiment of the vehicle is explained with reference to FIG. 2. The starting point for this is the exemplary embodiment of the system explained above.

In this exemplary embodiment, the vehicle 200 comprises a system that is in a similar form to the exemplary embodiment of the system 10 explained with reference to FIG. 1.

The vehicle 200 in this case has an energy store 210 that is coupled to an electrical load 220 and supplies said load with electrical energy.

The electrical load 220 may be a drive motor or other electric motor, for example. Other electrical loads 220 are also possible, for instance a heating device or a lighting device.

Conversely, electrical energy can also be transmitted from the electrical load 220 to the energy store 210, for instance when feeding in electrical power during recuperation.

The vehicle 200 also has a central control unit 230, which is connected to the energy store 210 and the electrical load 220 for data transfer purposes. The data connection can be used by the central control unit 230 to receive and send data, with in particular measurements being acquired and the measurements being used to generate control data.

An exemplary embodiment of the method is described with reference to FIGS. 3 and 4. The starting point for this is the exemplary embodiment of the system explained above, which is specified further hereinbelow.

In a first step 410, measurements of a terminal voltage of at least one battery cell 22a, 22b, 22c, 22d, 22e, 24a, 24b, 24c, 24d, 24e are acquired. The acquiring is carried out as a time series having a predefined length, which is configurable in the present example.

The graph shown by way of illustration in FIG. 3 plots the response 300 of a voltage V(t), specifically the terminal voltage of a battery cell 22a, 22b, 22c, 22d, 22e, 24a, 24b, 24c, 24d, 24e, over time t. A steady voltage level 310 can be seen, which substantially corresponds, or comes close, to an off-load voltage of the battery cell 22a, 22b, 22c, 22d, 22e, 24a, 24b, 24c, 24d, 24e, that is to say a terminal voltage without an electrical load demanding an electrical power.

Negative peaks 320 in the response, at which the terminal voltage falls, can also be seen. This indicates that electrical energy is drawn from the battery cell 22a, 22b, 22c, 22d, 22e, 24a, 24b, 24c, 24d, 24e, that is to say that a connected load is operated at a specific electrical power provided by the battery cell 22a, 22b, 22c, 22d, 22e, 24a, 24b, 24c, 24d, 24e.

Measurements representing the off-load level of the terminal voltage are shown as crosses in the graph 300. Other measurements that correspond, or come close, to the voltage response while the battery cell 22a, 22b, 22c, 22d, 22e, 24a, 24b, 24c, 24d, 24e is under load are represented as circles.

In order to be able to determine the state of charge of the battery cell 22a, 22b, 22c, 22d, 22e, 24a, 24b, 24c, 24d, 24e and, proceeding from this, of the energy store 20, the values of the terminal voltage that are acquired off load are needed. These correspond to the measurements of the off-load level 310, or come close to the off-load level 310.

In a step 420, a filtering of the series of measurements that was acquired in the first step 410 is performed. This step comprises a comparison operation, specifically comparing the acquired measurements with one another in order to determine the maximum value.

In the graph shown in FIG. 3, it becomes clear that this maximum value substantially corresponds to the absolute value of the off-load level 310.

In a step 430, a further filtering step is also carried out by determining the number of measurements above a specific threshold value.

The threshold value may be firmly predefined or can be determined dynamically, for instance 10% below the previously determined maximum value.

If the thus determined number of measurements above the threshold value is itself above a specific threshold, for instance more than 20% of the measurements, then it can be assumed that the maximum value is not an extraordinary deviation from the off-load level 310 of the voltage. It is thus possible to perform a plausibility check in this way.

In a step 440, output data are then generated. In the example, these comprise the determined maximum value and the number of measurements that are above the threshold value. These output data are transmitted via the data bus to the central control unit and can be processed further there, for instance to determine the state of charge of the energy store 20 or of the battery cell 22a, 22b, 22c, 22d, 22e, 24a, 24b, 24c, 24d, 24e. In other exemplary embodiments, the output data can also be transmitted to the central control unit via a data connection in a different form, for instance a wireless connection.

In the exemplary embodiment, there is also provision for the central control unit 30 to monitor an operating state of the energy store 20. This is accomplished in particular by acquiring what current is provided by the energy store 20. The direction of this current can be used in particular to detect when the energy store 20 is charged by recuperation or in another way. In the graph 300 shown in FIG. 3, this would lead to an upward deviation, and so determination of the maximum measurement would not lead to a suitable database for determining the state of charge. If a charging of the energy store 20 or of the at least one battery cell 22a, 22b, 22c, 22d, 22e, 24a, 24b, 24c, 24d, 24e is detected, then a “Reset” signal is generated and transmitted to the integrated cell monitoring unit 32, 34. Said unit then starts to acquire the plurality of the measurements again. The Reset signal can furthermore be generated when other events that distort the measurements are detected.

### LIST OF REFERENCE SIGNS

10 system
20 energy store
22 cell module
22a, 22b, 22c, 22d, 22e battery cell
24 cell module
24a, 24b, 24c, 24d, 24e battery cell
30 central control unit
32 integrated cell monitoring unit
34 integrated cell monitoring unit
40 data bus
200 vehicle
210 energy store
220 electrical load
230 central control unit
300 graph (voltage response)
310 off-load voltage
320 load peaks
410, 420, 430, 440 step

1. A method for operating an energy store comprising a plurality of battery cells, wherein acquiring a plurality of measurements of a terminal voltage of at least one battery cell;
filtering based on the acquired measurements;
generating a filtered measurement result, wherein the filtering of the measurements comprises a comparison operation;
generating output data; and
outputting the generated output data based on the filtered measurement result.

2. The method as claimed in claim 1, wherein the plurality of measurements are acquired as a time series.

3. The method according to claim 2, wherein an operating state is also detected; and the measurements are acquired depending on the operating state; wherein a control signal for resetting the acquired measurements is triggered based on the detected operating state, the control signal being generated in such a way that the acquiring of the measurements is resumed only after at least one of: the end of an event and/or that measurements acquired during the event are rejected.

4. The method as claimed in claim 3, wherein the comparison operation comprises determining a maximum or a minimum measurement of the plurality of measurements.

5. The method as claimed in claim 5, wherein the comparison operation comprises comparing the measurements with at least one limit value.

6. The method as claimed in claim 5, wherein the comparison operation comprises determining a number of measurements within a range.

7. The method as claimed in claim 6, wherein the comparison operation results in at least one limit of the range being determined.

8. The method as claimed in claim 7, wherein a configuration signal is also received; wherein the measurements are evaluated on the basis of the configuration signal.

9. The method as claimed in claim 8, wherein an operating state is also acquired; and the measurements are at least one of: acquired and/or evaluated on the basis of the operating state.

10. The method as claimed in claim 9, wherein the output value is used to determine and output a state of charge of at least one of: at least one battery cell and the energy store.

11. A system for operating an energy store comprising a plurality of battery cells, comprising
an acquiring module configured to acquire a plurality of measurements of a terminal voltage of at least one battery cell;
an evaluation module configured to perform a filtering based on the acquired measurements and to generate a filtered measurement result, wherein the filtering of the measurements comprises a comparison operation; and
an output module configured to generate and output output data based on the filtered result; wherein the acquiring module, the evaluation module and the output module are integrated in a cell monitoring unit that is associated with the at least one battery cell and that is coupled to a central control unit via at least one of: a data connection and a data bus.

12. The system as claimed in claim 11, wherein the central control unit is configured for detecting a charging of at least one of the energy store and the at least one battery cell and for then generating a reset signal and for transmitting said reset signal to the integrated cell monitoring unit, which is configured for then restarting to acquire a plurality of the measurements.

13. The method as claimed in claim 9, wherein a control signal for resetting the acquired measurements is triggered depending on the acquired operating state.
